(19) United States
(12) Patent Application Publication
(10) Pub. No.: US 2025/0311095 A1
(43) Pub. Date: Oct. 2, 2025

(54) WIRING BODY AND DISPLAY DEVICE

(71) Applicant: TDK Corporation, Tokyo (JP)

(72) Inventors: Hiroshi SHINGAI, Tokyo (JP); Daisuke SONODA, Tokyo (JP); Tatsuhiro SONE, Tokyo (JP); Michihiro KUMAGAE, Tokyo (JP); Hijiri KOIKE, Tokyo (JP); Kenichi TOCHI, Tokyo (JP)

(73) Assignee: TDK Corporation, Tokyo (JP)

(21) Appl. No.: 19/091,909

(22) Filed: Mar. 27, 2025

(30) Foreign Application Priority Data
Mar. 28, 2024 (JP) 2024-054645

(51) Int. Cl. H05K 1/02

(52) U.S. Cl. CPC H05K 1/0296; H05K 2201/10128

(57) ABSTRACT

A wiring body includes a substrate, and a conductor layer provided on the substrate and including an electroconductive line extending in a predetermined extending direction, in which in a cross-sectional view taken along a direction orthogonal to the extending direction, the electroconductive line includes a tapered portion in which a width of the electroconductive line increases toward one side away from the substrate in a height direction, and an expanded portion disposed on the one side with respect to the tapered portion and having the width greater than a width of the tapered portion, and the expanded portion protrudes outward in a width direction and includes a curved portion.

### CROSS-REFERENCE TO RELATED APPLICATION

This application is based upon and claims the benefit of priority from Japanese Patent Application No. 2024-054645, filed on Mar. 28, 2024, the entire contents of which are incorporated herein by reference.

### TECHNICAL FIELD

The present disclosure relates to a wiring body and a display device.

### BACKGROUND

A wiring body has been conventionally known which includes a substrate, a mesh-like conductor pattern provided on the substrate, and a resin layer provided on the substrate (for example, Japanese Unexamined Patent Publication No. 2021-163571). A trench is formed in the resin layer, and an electroconductive line of the conductor pattern is formed in the trench.

### SUMMARY

A wiring body according to an aspect of the present disclosure includes a substrate, and a conductor layer provided on the substrate and including an electroconductive line extending in a predetermined extending direction, in which in a cross-sectional view taken along a direction orthogonal to the extending direction, the electroconductive line includes a tapered portion in which a width of the electroconductive line increases toward one side away from the substrate in a height direction, and an expanded portion disposed on the one side with respect to the tapered portion and having the width greater than a width of the tapered portion, and the expanded portion protrudes outward in a width direction and includes a curved portion.

A display device according to an aspect of the present disclosure includes the wiring body.

### BRIEF DESCRIPTION OF THE DRAWINGS

FIG. 1 is a plan view illustrating an electroconductive film including a wiring body according to an embodiment;

FIG. 2 is a cross-sectional view taken along the line II-II in FIG. 1;

FIG. 3 is a cross-sectional view illustrating an electroconductive film according to a modification;

FIG. 4 is a cross-sectional view illustrating a display device according to an embodiment;

FIG. 5 is a plan view of an antenna including a wiring body;

FIG. 6 is an enlarged cross-sectional view of a wiring body;

FIG. 7 is an enlarged cross-sectional view in which an expanded portion and a part of a curved surface in FIG. 6 are enlarged; and

FIG. 8 is a view in which a resin layer is removed from FIG. 6.

### DETAILED DESCRIPTION

Here, in the wiring body, if the volume of the electroconductive line is reduced in order to prevent the influence on the visibility of the electroconductive line, there is a problem with transmission loss occurring when the wiring body is used as an antenna or the like. Therefore, it has been urged to reduce the transmission loss while reducing the influence on the visibility of the electroconductive line.

In view of the above, an object of the present disclosure is to provide a wiring body capable of reducing the transmission loss while reducing the influence on the visibility of the electroconductive line, and a display device.

According to an aspect of the present disclosure, it is possible to provide a wiring body capable of reducing the transmission loss while reducing the influence on the visibility of the electroconductive line, and a display device.

Hereinafter, some embodiments of the present disclosure will be described in detail. However, the present disclosure is not limited to the following embodiments.

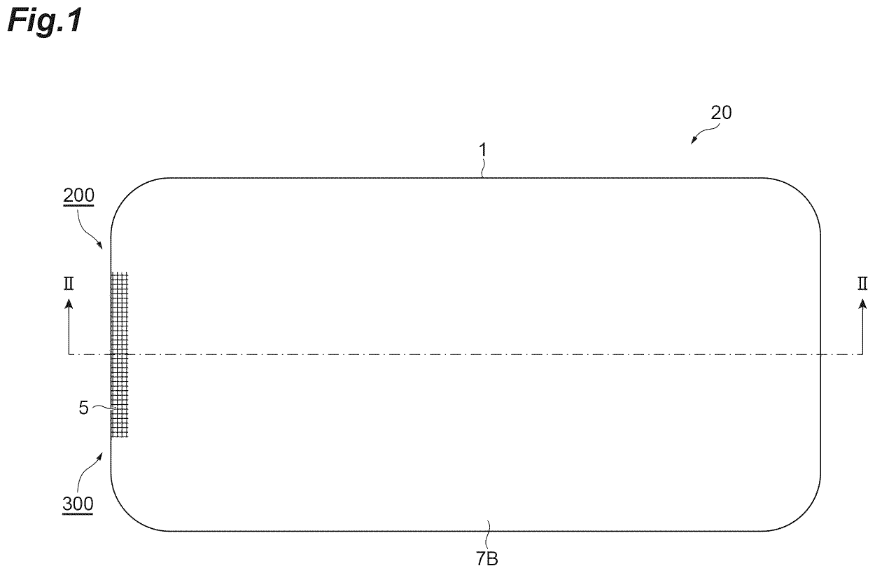

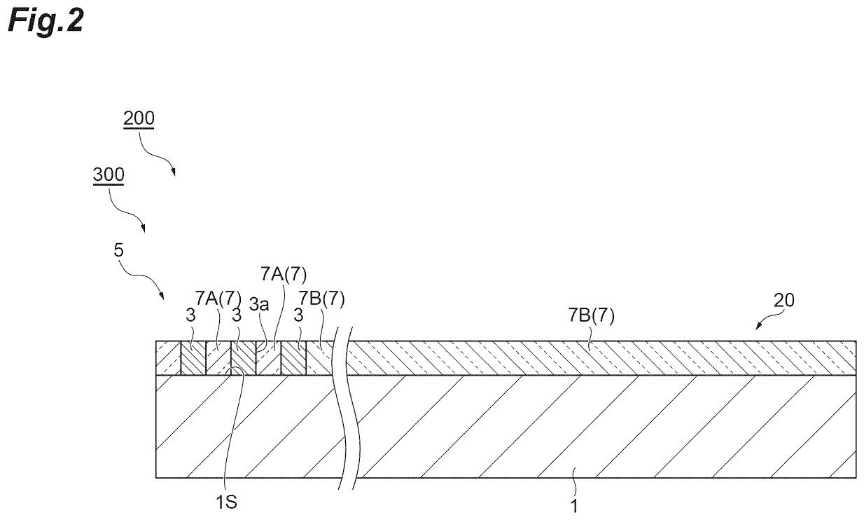

FIG. 1 is a plan view illustrating an electroconductive film including a wiring body 200 according to an embodiment of the present disclosure, and FIG. 2 is a cross-sectional view taken along the line II-II in FIG. 1. An electroconductive film 20 includes an antenna 300, and the antenna 300 includes the wiring body 200. The electroconductive film 20 illustrated in FIGS. 1 and 2 includes a film-like light transmissive substrate 1 (substrate), a conductor layer 5 provided on one main surface 1S of the light transmissive substrate 1, and a resin layer 7 provided on that one main surface 1S of the light transmissive substrate 1. The conductor layer 5 has a conductor portion 3 that extends in a direction along the main surface 1S of the light transmissive substrate 1 and has a portion having a pattern including a plurality of openings 3a. The resin layer 7 includes an insulating resin portion 7A filled in the opening 3a of the conductor portion 3, and a light transmissive resin layer 7B provided on the outer peripheral side of the conductor portion 3. In FIG. 2, the conductor layer 5 is illustrated in a deformed manner, and the width of the conductor portion 3 is illustrated in an emphasized manner. The thickness of each layer is also illustrated in a deformed manner. Details of the thickness of each layer will be described later. In the example illustrated in FIG. 1, the conductor layer 5 is formed near one short side of the electroconductive film 20, but the position where the conductor layer 5 is formed is not particularly limited, and the conductor layer 5 may be formed near a long side.

The light transmissive substrate 1 has optical transparency to an extent required when the electroconductive film 20 is incorporated in a display device. Specifically, the total light transmittance of the light transmissive substrate 1 may be 90 to 100%. The light transmissive substrate 1 may have a haze of 0 to 5%.

The light transmissive substrate 1 may be, for example, a transparent resin film, and examples thereof include a film of polyethylene terephthalate (PET), polycarbonate (PC), polyethylene naphthalate (PEN), cycloolefin polymer (COP), or polyimide (PI). Alternatively, the light transmissive substrate 1 may be a glass substrate.

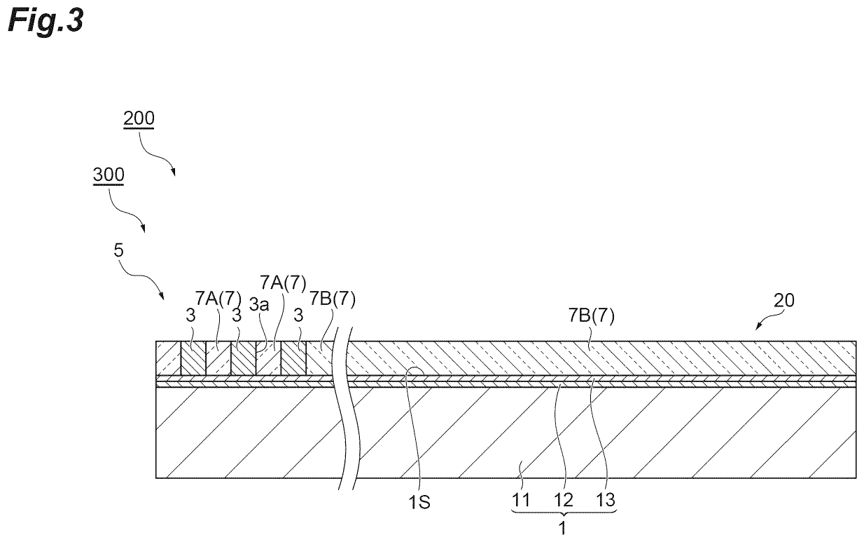

For example, as illustrated in FIG. 3, the light transmissive substrate 1 may be a laminate including a light transmissive support film 11, and an intermediate resin layer 12 and an underlying layer 13 sequentially provided on the support film 11. The support film 11 can be the transparent resin film. The underlying layer 13 is a layer provided in order to form the conductor portion 3 by electroless plating or the like. In a case where the conductor portion 3 is formed by another method, the underlying layer 13 is not necessarily provided. It is not essential that the intermediate resin layer 12 is provided between the support film 11 and the underlying layer 13.

The thickness of the light transmissive substrate 1 or the support film 11 constituting the same may be 10 μm or more, 20 μm or more, or 35 μm or more, and may be 500 μm or less, 200 μm or less, or 100 μm or less.

Providing the intermediate resin layer 12 can improve adhesion between the support film 11 and the underlying layer 13. In a case where the underlying layer 13 is not provided, the intermediate resin layer 12 is provided between the support film 11 and the light transmissive resin layer 7B, so that adhesion between the support film 11 and the light transmissive resin layer 7B can be improved.

The intermediate resin layer 12 may be a layer containing a resin and an inorganic filler. Examples of the resin constituting the intermediate resin layer 12 include an acrylic resin. Examples of the inorganic filler include silica.

The thickness of the intermediate resin layer 12 may be, for example, 5 nm or more, 100 nm or more, or 200 nm or more, and may be 10 μm or less, 5 μm or less, or 2 μm or less.

The underlying layer 13 may be a layer containing a catalyst and a resin. The resin may be a cured product of a curable resin composition. Examples of a curable resin contained in the curable resin composition include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The catalyst contained in the underlying layer 13 may be an electroless plating catalyst. The electroless plating catalyst may be a metal selected from Pd, Cu, Ni, Co, Au, Ag, Pd, Rh, Pt, In, and Sn, or may be Pd. The catalyst may be one kind alone or a combination of two or more kinds. Usually, the catalyst is dispersed in the resin as catalyst particles.

The content of the catalyst in the underlying layer 13 may be 3 mass % or more, 4 mass % or more, or 5 mass % or more, and may be 50 mass % or less, 40 mass % or less, or 25 mass % or less with respect to the total amount of the underlying layer 13.

The thickness of the underlying layer 13 may be 10 nm or more, 20 nm or more, or 30 nm or more, and may be 500 nm or less, 300 nm or less, or 150 nm or less.

The light transmissive substrate 1 may further include a protective layer provided on a main surface of the support film 11 opposite to the light transmissive resin layer 7B and the conductor portion 3. Providing the protective layer prevents the support film 11 from being scratched. The protective layer can be a layer similar to the intermediate resin layer 12. The thickness of the protective layer may be 5 nm or more, 50 nm or more, or 500 nm or more, and may be 10 μm or less, 5 μm or less, or 2 μm or less.

The conductor portion 3 constituting the conductor layer 5 includes a part having a pattern including the openings 3a. The pattern including the openings 3a is a mesh-like pattern that is formed by a plurality of linear portions intersecting each other and includes the plurality of openings 3a regularly arranged. The conductor portion 3 having the mesh-like pattern can favorably function as, for example, a radiation conductor and a feed line of the antenna 300. In addition, the conductor portion 3 may have a planar pattern that functions as a terminal and a ground pad portion and has no openings 3a. The configuration of the pattern of the conductor portion 3 in the conductor layer 5 will be detailed later.

The conductor portion 3 may contain metal. The conductor portion 3 may contain at least one metal selected from copper, nickel, cobalt, palladium, silver, gold, platinum, and tin, or may contain copper. The conductor portion 3 may be metal plating formed by a plating method. The conductor portion 3 may further contain a nonmetallic element such as phosphorus within a range in which appropriate conductivity is maintained.

The conductor portion 3 may be a laminate including a plurality of layers. In addition, the conductor portion 3 may have a blackened layer as a surface layer portion on a side opposite to the light transmissive substrate 1. The blackened layer can contribute to improvement in visibility of a display device in which the electroconductive film is incorporated.

The insulating resin portion 7A is formed of a light transmissive resin and is provided so as to fill the openings 3a of the conductor portion 3, and the insulating resin portion 7A and the conductor portion 3 usually form a flat surface.

The light transmissive resin layer 7B is formed of a light transmissive resin. The total light transmittance of the light transmissive resin layer 7B may be 90 to 100%. The light transmissive resin layer 7B may have a haze of 0 to 5%.

The difference between the light transmissive substrate 1 (or the refractive index of the support film constituting the light transmissive substrate 1) and the refractive index of the light transmissive resin layer 7B may be 0.1 or less. As a result, good visibility of a display image is more easily achieved. The refractive index (nd 25) of the light transmissive resin layer 7B may be, for example, 1.0 or more, and may be 1.7 or less, 1.6 or less, or 1.5 or less. The refractive index can be measured by a spectroscopic ellipsometer. In terms of uniformity of the optical path length, the conductor portion 3, the insulating resin portion 7A, and the light transmissive resin layer 7B may have substantially the same thickness.

The resin forming the insulating resin portion 7A and the light transmissive resin layer 7B may be a cured product of a curable resin composition (photocurable resin composition or thermosetting resin composition). The curable resin composition forming the insulating resin portion 7A and/or the light transmissive resin layer 7B includes a curable resin, and examples thereof include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The resin forming the insulating resin portion 7A and the resin forming the light transmissive resin layer 7B may be the same. Since the insulating resin portion 7A and the light transmissive resin layer 7B formed of the same resin have the same refractive index, the uniformity of the optical path length transmitted through the electroconductive film 20 can be further improved. In a case where the resin forming the insulating resin portion 7A and the resin forming the light transmissive resin layer 7B are the same, for example, the insulating resin portion 7A and the light transmissive resin layer 7B can be easily and collectively formed by forming a pattern from one curable resin layer by an imprinting method or the like.

The electroconductive film 20 can be manufactured, for example, by a method including pattern formation by the imprinting method. An example of a method for manufacturing the electroconductive film 20 includes: preparing the light transmissive substrate 1 including the support film, the intermediate resin layer, and the underlying layer containing the catalyst, the intermediate resin layer, and the underlying layer being provided on one main surface of the support film; forming the curable resin layer on the main surface 1S on the underlying layer side of the light transmissive substrate 1; forming a trench in which the underlying layer is exposed by an imprinting method using a mold having a convex portion; and forming the conductor portion 3 filling the trench by an electroless plating method in which metal plating is grown from the underlying layer. The curable resin layer is cured in a state where the mold is pushed into the curable resin layer to thereby form collectively the insulating resin portion 7A having a pattern including an opening with an inverted shape of the convex portion of the mold, and the light transmissive resin layer 7B. The method for forming the insulating resin portion 7A having the pattern including the opening is not limited to the imprinting method, and any method such as photolithography can be applied.

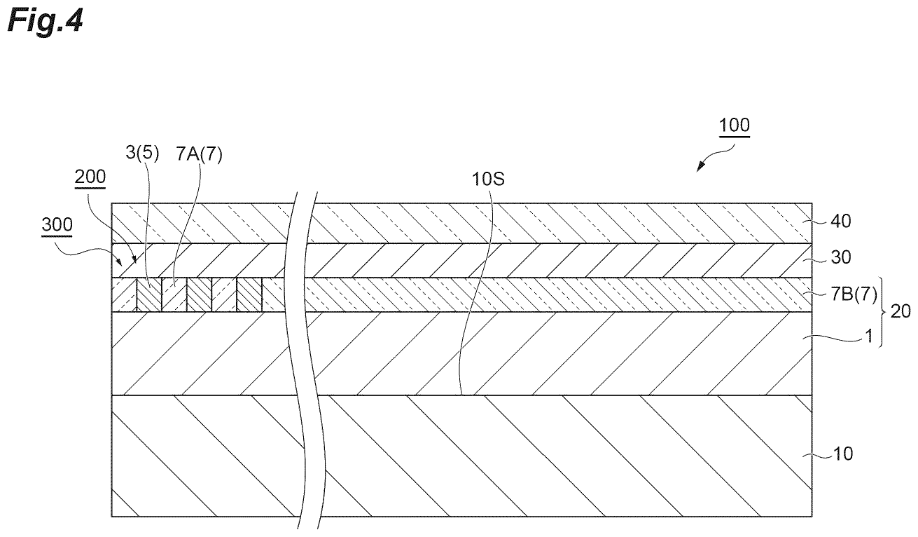

The electroconductive film described above as an example can be incorporated into a display device as, for example, a planar transparent antenna. The display device may be, for example, a liquid crystal display device or an organic EL display device. FIG. 4 is a cross-sectional view illustrating an embodiment of a display device in which an electroconductive film is incorporated. A display device 100 illustrated in FIG. 4 includes an image display unit 10 having an image display region 10S, an electroconductive film 20, a polarizing plate 30, and a cover glass 40. The electroconductive film 20, the polarizing plate 30, and the cover glass 40 are laminated, in this order from the image display unit 10 side, on the image display region 10S side of the image display unit 10. The configuration of the display device is not limited to the form of FIG. 4, and can be appropriately changed as necessary. For example, the polarizing plate 30 may be provided between the image display unit 10 and the electroconductive film 20. The image display unit 10 may be, for example, a liquid crystal display unit. As the polarizing plate 30 and the cover glass 40, those commonly used in a display device can be used. The polarizing plate 30 and the cover glass 40 are not necessarily provided. Light for image display emitted from the image display region 10S of the image display unit 10 passes through a path having a highly uniform optical path length including the electroconductive film 20. This makes it possible to display an image with high uniformity and favorable quality with suppressed moire.

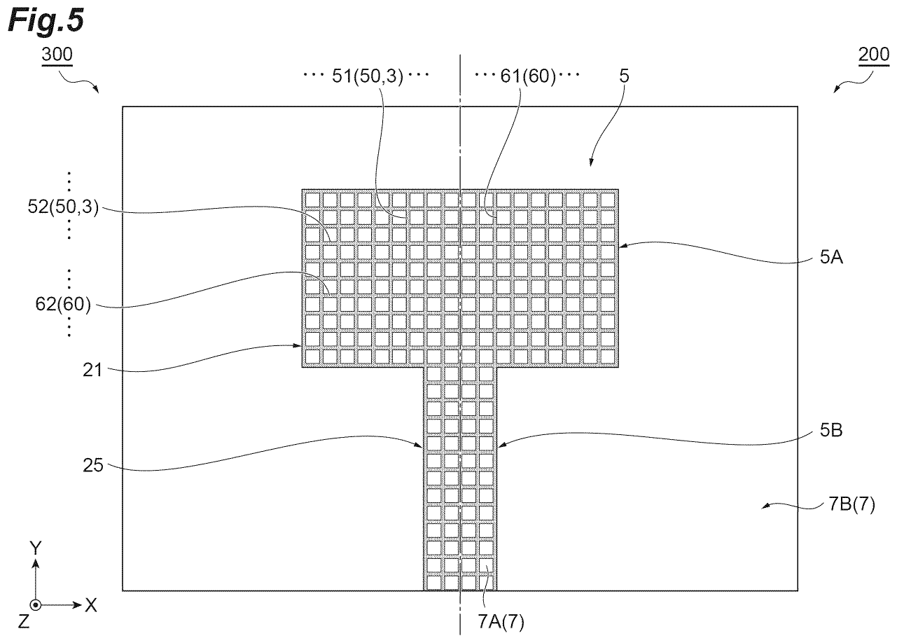

Next, the configurations of the conductor layer 5 and its periphery will be described in more detail with reference to FIG. 5. FIG. 5 is a plan view of the antenna 300 including the wiring body 200. FIG. 5 is an enlarged view of a part of the conductor layer 5. In the following description, it is assumed that XY coordinates are set with respect to a plane parallel to the main surface 1S. The Y-axis direction is a direction along the main surface 1S, and corresponds to a direction orthogonal to a side portion of the electroconductive film 20 in the example illustrated in FIG. 1. The center side of the electroconductive film 20 is defined as a positive side in the Y-axis direction, and the outer peripheral side of the electroconductive film 20 is defined as a negative side in the Y-axis direction. The X-axis direction is a direction orthogonal to the Y-axis direction along the main surface S1, and corresponds to a direction in which the side portion of the electroconductive film 20 extends in the example illustrated in FIG. 1. One side in which the side portion of the electroconductive film 20 extends is defined as a positive side in the X-axis direction, and the other side is defined as a negative side in the X-axis direction. A direction orthogonal to the X-axis direction and the Y-axis direction is defined as a Z-axis direction. The side on which the resin layer 7 is provided on the light transmissive substrate 1 is defined as a positive side in the Z-axis direction.

As illustrated in FIG. 5, the mesh-like pattern of the conductor layer 5 includes a plurality of first electroconductive lines 51 and a plurality of second electroconductive lines 52. The first electroconductive line 51 is the linear conductor portion 3 extending parallel to the Y-axis direction. The plurality of first electroconductive lines 51 is arranged to be spaced apart from each other in the X-axis direction. The plurality of first electroconductive lines 51 is arranged to be spaced apart at a constant pitch. The second electroconductive line 52 is the linear conductor portion 3 extending parallel to the X-axis direction. The plurality of second electroconductive lines 52 is arranged to be spaced apart from each other in the Y-axis direction. The plurality of second electroconductive lines 52 is arranged to be spaced apart at a constant pitch. The thickness of the electroconductive lines 51 and 52 is not particularly limited, and may be set to, for example, 1 to 3 μm. The pitch of the electroconductive lines 51 and 52 is not particularly limited, and may be set to, for example, 100 to 300 μm. The first electroconductive line 51 does not need to be parallel to the Y-axis direction as long as the first electroconductive line 51 extends in the Y-axis direction, and the second electroconductive line 52 does not need to be parallel to the X-axis direction as long as the second electroconductive line 52 extends in the X-axis direction. In a case where the electroconductive lines 51 and 52 are described without distinguishing therebetween, they may be referred to as an electroconductive line 50.

The conductor layer 5 includes a radiating element portion 5A and a power supply portion 5B. The radiating element portion 5A is a region that radiates a signal as an antenna. The radiating element portion 5A has a rectangular shape having two sides parallel to the Y-axis direction and two sides parallel to the X-axis direction. The power supply portion 5B is a region that feeds power to the radiating element portion 5A. The power supply portion 5B has a belt-like shape extending parallel to the Y-axis direction. The power supply portion 5B is connected to the side of the radiating element portion 5A on the negative side in the Y-axis direction. The power supply portion 5B is connected to a terminal (not illustrated).

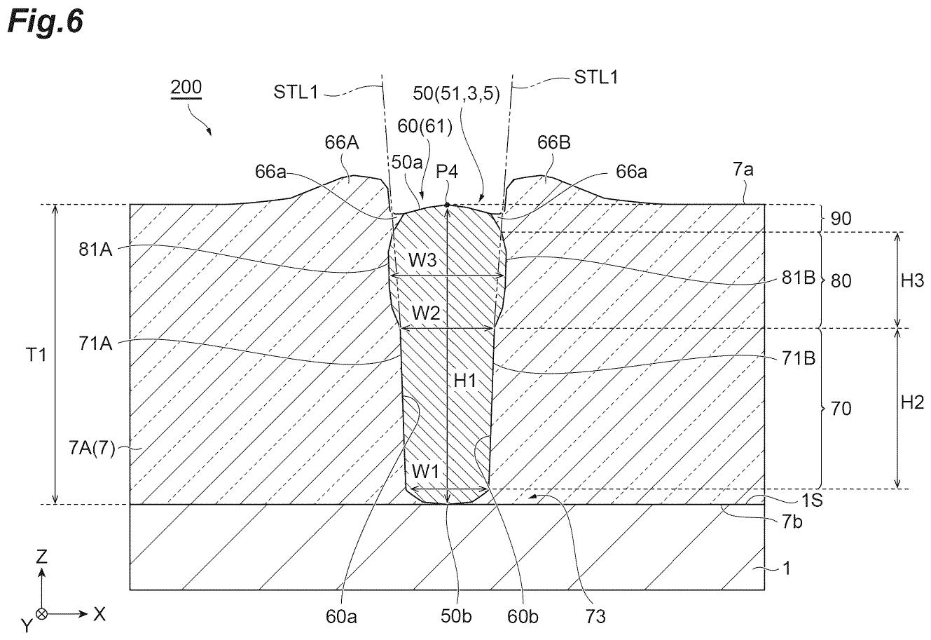

Next, the configurations of the resin layer 7 and the conductor layer 5 will be described in more detail with reference to FIG. 6 in addition to FIG. 5. FIG. 6 is a cross-sectional view of the wiring body 200. In the following description, the words “upper” and “lower” will be used, but the words are not intended to limit the posture of the wiring body 200 during use. In some cases, the positive side in the Z-axis direction is referred to as “upper”, and the negative side in the Z-axis direction is referred to as “lower”. As described above, the resin layer 7 is provided on the light transmissive substrate 1 as illustrated in FIG. 6. The resin layer 7 is provided so as to cover the main surface 1S on the positive side in the Z-axis direction of the light transmissive substrate 1. The resin layer 7 has an upper surface 7a on the positive side in the Z-axis direction and a lower surface 7b on the negative side in the Z-axis direction. The lower surface 7b on the negative side is provided so as to be in contact with the main surface 1S of the light transmissive substrate 1.

In the resin layer 7, a mesh-like trench 60 passing through the resin layer 7 in the Z-axis direction (thickness direction) is formed. The mesh-like trench 60 extends from the upper surface 7a on the positive side to the lower surface 7b on the negative side in the Z-axis direction of the resin layer 7. The electroconductive line 50 of the conductor layer 5 is disposed in the mesh-like trench 60. As illustrated in FIG. 5, the mesh-like trench 60 includes a first trench 61 in which the first electroconductive line 51 is disposed and a second trench 62 in which the second electroconductive line 52 is disposed. The first trenches 61 are arranged at a pitch and width corresponding to the first electroconductive lines 51 described above. The second trenches 62 are arranged at a pitch and width corresponding to the second electroconductive lines 52 described above. That is, the first trenches 61 are linear trenches that extend parallel to the Y-axis direction. The plurality of first trenches 61 is arranged to be spaced apart from each other in the X-axis direction. The plurality of first trenches 61 is arranged to be spaced apart at a constant pitch. The second trenches 62 are linear trenches that extend parallel to the X-axis direction. The plurality of second trenches 62 is arranged to be spaced apart from each other in the Y-axis direction. The plurality of second trenches 62 is arranged to be spaced apart at a constant pitch.

With such a configuration, the conductor layer 5 passes through the resin layer 7. That is, the electroconductive line 50 extends from the upper surface 7a on the positive side of the resin layer 7 to the lower surface 7b on the negative side of the resin layer 7. The electroconductive line 50 has an upper surface 50a extending to the same position as the upper surface 7a of the resin layer 7 or a position near the upper surface 7a. The electroconductive line 50 has a lower surface 50b that is in contact with the main surface 1S of the light transmissive substrate 1. The state in which the conductor layer 5 passes through the resin layer 7 is a state in which the electroconductive line 50 is disposed in the trench 60 of the resin layer 7 to reach the main surface 1S of the light transmissive substrate 1. Accordingly, the upper surface 50a of the electroconductive line 50 does not need to reach the upper surface 7a of the resin layer 7, and may be disposed on the negative side in the Z-axis direction with respect to the upper surface 7a as described later.

Next, the cross-sectional shape of the electroconductive line 50 will be described in more detail with reference to FIG. 6. In FIG. 6, a cross section of the first electroconductive line 51 extending in the Y-axis direction is illustrated as the electroconductive line 50, and the second electroconductive line 52 extending in the X-axis direction and the periphery thereof also have the same structure. As illustrated in FIG. 6, the electroconductive line 50 includes a tapered portion 70, an expanded portion 80, and a curved surface 90 in order from the light transmissive substrate 1 side.

The tapered portion 70 is a portion in which the width of the electroconductive line 50 increases toward the positive side (one side) away from the light transmissive substrate 1 in the Z-axis direction (height direction). The tapered portion 70 of the electroconductive line 50 has side surfaces 71A and 71B facing each other in the width direction (here, the X-axis direction). The side surface 71A is disposed on one side in the width direction (negative side in the X-axis direction), and the side surface 71B is disposed on the other side in the width direction (positive side in the X-axis direction). A width dimension W1 at an end on the negative side in the Z-axis direction of the tapered portion 70 is smaller than a width dimension W2 at an end on the positive side in the Z-axis direction of the tapered portion 70. The side surfaces 71A and 71B each have a taper inclined such that a separation distance between the side surfaces 71A and 71B in the X-axis direction increases toward one side in the height direction (positive side in the Z-axis direction). The tapered portion 70 is a portion extending in a nearly straight line in a state where the side surfaces 71A and 71B are inclined in the Z-axis direction without being sharply bent or curved, in a cross-sectional view when viewed from the extending direction of the electroconductive line 50 (here, the Y-axis direction). The inclination angle of each of the side surfaces 71A and 71B with respect to the Z axis is not particularly limited, but may be set to 1 to 10°. A curved surface 73 is formed between the tapered portion 70 and the light transmissive substrate 1 such that the lower surface 50b protrudes in the Z-axis direction. The curved surface 73 does not correspond to the tapered portion 70. The tapered portion 70 may include a portion whose width does not change (does not incline) partially or which becomes narrower in the Z-axis direction. In the tapered portion 70, a configuration is possible in which only one of the side surfaces 71A and 71B is inclined so that the width of the electroconductive line 50 is increased, or, another configuration is possible in which the side surface 71A and the side surface 71B are inclined at different inclination angles so that the width of the electroconductive line 50 is increased.

The expanded portion 80 is a portion that is disposed on the positive side in the Z-axis direction with respect to the tapered portion 70 and is wider than the tapered portion 70. The expanded portion 80 is provided at a position adjacent to the tapered portion 70 on the positive side in the Z-axis direction. The expanded portion 80 has side surfaces 81A and 81B facing each other in the width direction (here, the X-axis direction). The side surface 81A is disposed on one side in the width direction (negative side in the X-axis direction), and the side surface 81B is disposed on the other side in the width direction (positive side in the X-axis direction). The expanded portion 80 protrudes outward in the width direction and includes a curved portion. Specifically, the side surfaces 81A and 81B of the expanded portion 80 may have a shape extending along the Z axis and may be curved so as to protrude outward in the width direction. The side surface 81A of the expanded portion 80 protrudes toward the negative side in the X-axis direction (outward in the width direction) and includes a curved portion. The side surface 81B of the expanded portion 80 protrudes toward the positive side in the X-axis direction (outward in the width direction) and includes a curved portion. However, each of the side surfaces 81A and 81B of the expanded portion 80 does not need to be curved in the entire region in the Z-axis direction, and may include a portion whose width does not partially change or which becomes narrower in the Z-axis direction. In addition, in FIG. 6, for convenience of description, the side surface 81A and the side surface 81B are illustrated as being bilaterally symmetrical, but do not need to be bilaterally symmetrical. Note that details of the range of the expanded portion 80 will be described later. The width dimension of the expanded portion 80 at any position in the Z-axis direction may be greater than the width dimension W2 of the tapered portion 70. The maximum width dimension of the expanded portion 80 is defined as a width dimension W3.

The curved surface 90 is the upper surface 50a of the electroconductive line 50 on the positive side in the Z-axis direction, and is a surface curved so as to protrude toward the positive side in the Z-axis direction. The curved surface 90 is provided in a region on the positive side in the Z-axis direction with respect to the expanded portion 80.

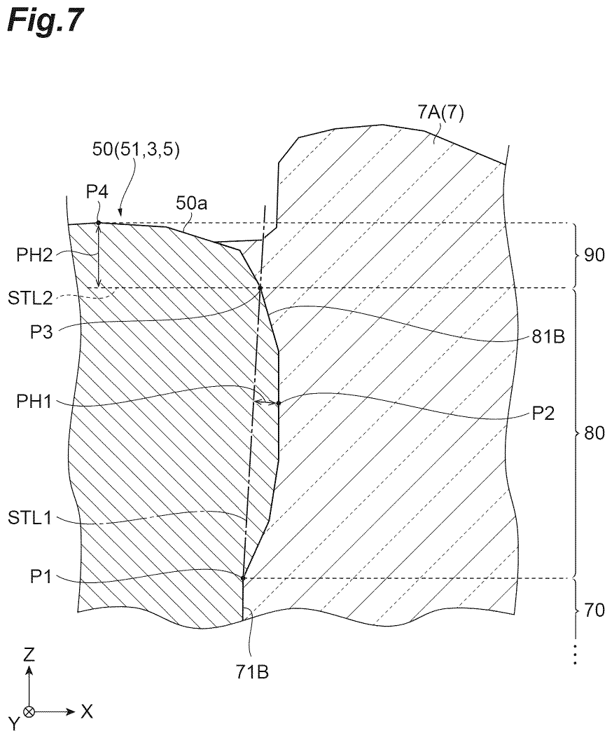

Here, the relationship between the protrusion height of the curved surface 90 and the protrusion height of the expanded portion 80 will be described with reference to FIG. 7. FIG. 7 is an enlarged cross-sectional view in which the expanded portion 80 and a part of the curved surface 90 in FIG. 6 are enlarged.

First, a protrusion height PH1 of the expanded portion 80 will be described. In the expanded portion 80, a boundary point P1 is set at an end on the negative side in the Z-axis direction. A reference line STL1 that passes through the boundary point P1 and extends in the Z-axis direction at the inclination angle of the tapered portion 70 is set. As also illustrated in FIG. 6, the reference line STL1 is set using a straight line connecting the lower end and the upper end of each of the side surfaces 71A and 71B. As illustrated in FIG. 7, in the expanded portion 80, an apex P2 is set at a position on the outermost side in the width direction (here, positive side in the X-axis direction). At this time, a separation distance between the apex P2 and the reference line STL1 in a direction perpendicular to the reference line STL1 is set as the protrusion height PH1 of the expanded portion 80.

Next, a protrusion height PH2 of the curved surface 90 will be described. In a cross-sectional view when viewed from the extending direction of the electroconductive line 50 (here, the Y-axis direction), at a position on the positive side in the Z-axis direction with respect to the apex P2 of the expanded portion 80, a boundary point P3 is set by defining a portion intersecting the reference line STL1 as an end on the positive side in the Z-axis direction of the expanded portion 80. A reference line STL2 that passes through the boundary point P3 and is parallel to the X-axis direction is set. On the curved surface 90, an apex P4 is set at a position on the furthest positive side in the Z-axis direction. At this time, a separation distance between the apex P4 and the reference line STL2 in the Z-axis direction is set as the protrusion height PH2 of the curved surface 90. The protrusion height PH1 of the expanded portion 80 is smaller than the protrusion height PH2 of the curved surface 90. Although not particularly limited, the protrusion height PH1 of the expanded portion 80 is set in a range of 0.05 to 0.25 μm. The protrusion height PH2 of the curved surface 90 is set in a range of 0.15 to 0.35 μm.

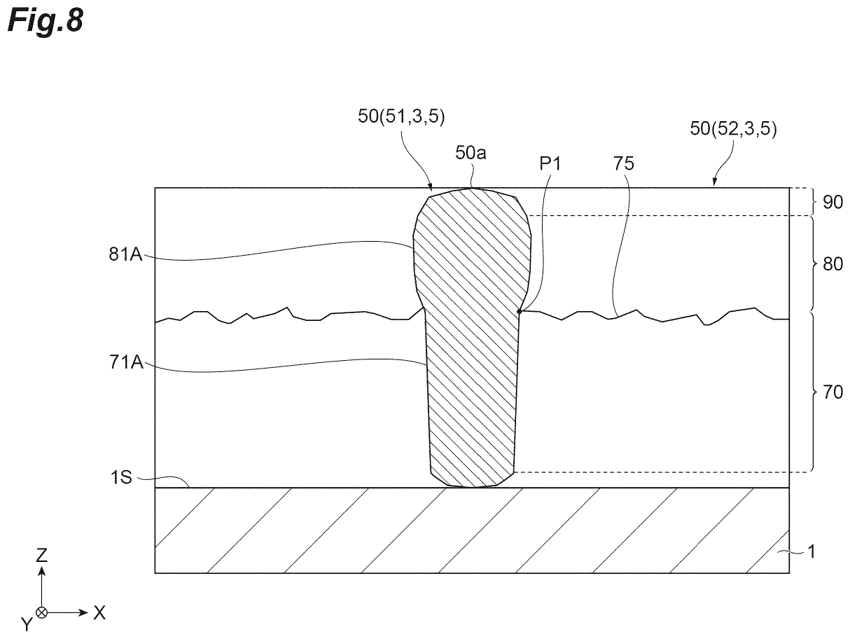

Next, a state when the electroconductive line 50 is viewed from the width direction will be described with reference to FIG. 8. FIG. 8 is a view in which the resin layer 7 is removed from FIG. 6. FIG. 8 illustrates the side surface 71A of the tapered portion 70 and the side surface 81A of the expanded portion 80 of the second electroconductive line 52 extending in the X-axis direction. Here, a boundary between the tapered portion 70 and the expanded portion 80 is defined as a boundary portion 75. The boundary portion 75 is located at a position of an end of the expanded portion 80 on the negative side (the other side opposite to one side) in the Z-axis direction, and corresponds to the part where the boundary point P1 is set in FIG. 7. The height position of the boundary portion 75 of the second electroconductive line 52 is not constant but randomly changes at each position in the X-axis direction that is the extending direction of the second electroconductive line 52. As a result, in the expanded portion 80, the position of the boundary portion 75, which is the end on the negative side in the Z-axis direction, changes along the extending direction of the electroconductive line 50. At this time, the height dimension of the expanded portion 80 changes along the extending direction of the electroconductive line 50. This relationship similarly holds for the first electroconductive line 51 extending in the Y-axis direction.

As illustrated in FIG. 6, the trench 60 has inner surfaces 60a and 60b facing each other in the width direction. The side surfaces 71A and 71B, the side surfaces 81A and 81B, and (a part of) the curved surface 90 of the electroconductive line 50 are in surface contact with the inner surfaces 60a and 60b of the trench 60. The resin layer 7 has raised portions 66A and 66B protruding from both sides of the trench 60 to one side (positive side in the Z-axis direction) in the height direction with respect to the upper surface 7a of the resin layer 7. The raised portions 66A and 66B are portions where a part of the resin layer 7 is raised so as to be higher on one side in the height direction than the upper surface 7a of the resin layer 7 on both sides in the width direction of the curved surface 90. The height relationship between the height of the apex P4 of the curved surface 90 of the electroconductive line 50 and the upper surface 7a of the resin layer 7 or the upper ends of the raised portions 66A and 66B is not particularly limited. The raised portions 66A and 66B cover a part on both end sides of the curved surface 90 in the width direction with inner peripheral edges 66a. With such a structure, the expanded portion 80 has a structure in which at least a part of the expanded portion 80 is covered with the resin layer 7 when viewed from a direction orthogonal to the main surface 1S of the light transmissive substrate 1 (Z-axis direction). In the present embodiment, at least the curved shape in the vicinity of the side surfaces 81A and 81B is covered with the resin layer 7.

Next, a dimensional relationship of the electroconductive line 50 will be described with reference to FIG. 6. A height H1 of the electroconductive line 50 and a thickness T1 (dimension in the height direction) of the resin layer 7 may be 1.5 to 5.0 μm. In the present embodiment, the height H1 (dimension in the height direction) is greater than the width (dimension in the X-axis direction) of the electroconductive line 50. An aspect ratio (height/width) obtained by dividing the height H1 by the width of the electroconductive line 50 is set to be greater than 1. The aspect ratio may be 2 or more. The width dimension used for determining the aspect ratio is the largest width dimension W3 in the electroconductive line 50. The width dimension W3 is set to about 0.5 to 2.0 μm. The largest width dimension W3 of the electroconductive line 50 may be 120 to 160% greater than the width dimension W2 of the tapered portion 70. The largest width dimension W2 of the tapered portion 70 may be 140 to 180% greater than the width dimension W1 on the lower surface 50b side.

A height dimension H3 of the expanded portion 80 may be smaller than a height dimension H2 of the tapered portion 70. For example, the height dimension H3 of the expanded portion 80 may be 35 to 75% of the height dimension H2 of the tapered portion 70. In addition, an aspect ratio obtained by dividing the height dimension H3 of the expanded portion 80 by the width dimension W3 thereof may be smaller than 1. Further, the aspect ratio may be smaller than 0.85.

Next, functions and effects of the wiring body 200 and the display device 100 according to the present embodiment will be described.

The wiring body 200 according to the present embodiment includes the light transmissive substrate 1 and the conductor layer 5 that is provided on the light transmissive substrate 1 and has the electroconductive line 50 extending linearly in a predetermined extending direction, and in a cross-sectional view taken along a direction orthogonal to the extending direction, the electroconductive line 50 has the tapered portion 70 in which the width of the electroconductive line 50 increases toward one side away from the light transmissive substrate 1 in the height direction, and the expanded portion 80 that is disposed on one side with respect to the tapered portion 70 and has a width greater than that of the tapered portion 70, and the expanded portion 80 protrudes outward in the width direction and includes a curved portion.

In the wiring body 200, the electroconductive line 50 has the tapered portion 70 and the expanded portion 80 in a cross-sectional view taken along a direction orthogonal to the extending direction. In the tapered portion 70 disposed in the conductor layer 5 on the light transmissive substrate 1 side, the width of the electroconductive line 50 increases toward one side away from the light transmissive substrate 1 in the height direction. According to such a shape, the line of sight from the upper surface side of the conductor layer 5 can be prevented from being blocked by the side surfaces 71A and 71B as compared with a case where the side surfaces 71A and 71B are parallel to the Z-axis direction. On the other hand, the expanded portion 80 is provided on the upper surface side of the conductor layer 5. Since the expanded portion 80 has a width greater than that of the tapered portion 70, protrudes outward in the width direction, and includes a curved portion, the volume of the electroconductive line 50 can be increased in the vicinity of the upper surface of the conductor layer 5. Therefore, due to the skin effect, transmission loss can be reduced particularly in a high-frequency antenna. The expanded portion 80 is disposed on one side in the height direction with respect to the tapered portion 70. Therefore, it is possible to reduce the influence on the visibility of the expanded portion 80 by avoiding a situation where the expanded portion 80 having a large volume is disposed at a deep position from the upper surface of the conductor layer 5. As described above, the transmission loss can be reduced while the influence on the visibility of the electroconductive line is reduced.

The upper surface 50a of the electroconductive line 50 on one side in the height direction is the curved surface 90 protruding to one side, and the protrusion height PH1 of the expanded portion 80 may be smaller than the protrusion height PH2 of the curved surface 90. In this case, when the line of sight is incident at a large angle of incidence in the vicinity of the upper surface 50a of the electroconductive line 50, the line of sight is blocked at the edge in the width direction on the planar upper surface 50a, but, in the case of the curved surface 90, the line of sight can be prevented from being blocked because the edges in the width direction of the curved surface 90 are lowered. Therefore, the influence on the visibility can be reduced. Further, the protrusion height PH1 of the expanded portion 80 is prevented from being excessively large. The expanded portion 80 can thus reduce the influence on the visibility while the transmission loss is reduced.

The wiring body 200 may further include the resin layer 7 provided on the light transmissive substrate 1, and the resin layer 7 may have the trench 60 in which the electroconductive line 50 is disposed. In this case, the adhesion of the electroconductive line 50 can be increased on the light transmissive substrate 1.

In the expanded portion 80, a position of the end on the other side opposite to one side (that is, the boundary portion 75) may change along the extending direction of the electroconductive line 50. In this case, the boundary portion 75 has a shape that changes randomly to wedge into the resin layer 7, so that an anchor effect can be achieved. Therefore, the adhesion of the electroconductive line 50 to the resin layer 7 can be increased on the light transmissive substrate 1.

In the expanded portion 80, at least a part of the expanded portion 80 may be covered with the resin layer 7 when viewed from a direction orthogonal to the main surface 1S of the light transmissive substrate 1. In this case, the influence on the visibility with respect to the line of sight from the oblique direction can be reduced as compared with a case where the entire expanded portion 80 is not covered with the resin layer 7 when viewed from the direction orthogonal to the main surface 1S of the light transmissive substrate 1.

An aspect ratio obtained by dividing the height dimension of the electroconductive line 50 by the width dimension may be greater than 1. In this case, the electroconductive line 50 is made thinner to prevent an increase in the visibility of the conductor portion, and the conductor cross-sectional area is increased by increasing the aspect ratio to reduce the resistance value, so that the transmission loss can be reduced.

In this case, the influence on the visibility of the electroconductive line 50 can be reduced by preventing the expanded portion 80 from becoming too large in the height direction (Z-axis direction).

An aspect ratio obtained by dividing the height dimension of the expanded portion 80 by the width dimension may be smaller than 1. In this case, the transmission loss can be reduced by using a shape in which the size of the expanded portion 80 in the width direction is secured.

The display device 100 according to an aspect of the present disclosure includes the wiring body 200.

According to the display device 100, functions and effects similar to those of the wiring body 200 described above can be achieved.

The present disclosure is not limited to the embodiment described above.

For example, the shapes of the electroconductive line 50 and the resin layer 7 are not limited to those illustrated in FIG. 6, and can be appropriately changed without departing from the gist of the present disclosure. The height dimension of each portion, the dimensional relationship in the width direction, the relationship of the aspect ratio, and the like are not limited to the above-described embodiment, and can be appropriately changed. In particular, the shapes of the expanded portion 80 and the vicinity of the curved surface 90 can be appropriately changed.

### [Aspect 1]

A wiring body including:
a substrate; and a conductor layer provided on the substrate and including an electroconductive line extending in a predetermined extending direction, in which
in a cross-sectional view taken along a direction orthogonal to the extending direction, the electroconductive line includes
   a tapered portion in which a width of the electroconductive line increases toward one side away from the substrate in a height direction, and
   an expanded portion disposed on the one side with respect to the tapered portion and having the width greater than a width of the tapered portion, and
the expanded portion protrudes outward in a width direction and includes a curved portion.

### [Aspect 2]

The wiring body according to aspect 1, in which a surface of the electroconductive line on the one side in the height direction is a curved surface protruding toward the one side, and
a protrusion height of the expanded portion is smaller than a protrusion height of the curved surface.

### [Aspect 3]

The wiring body according to aspect 1 or 2, further including a resin layer provided on the substrate, in which
the resin layer has a trench in which the electroconductive line is disposed.

### [Aspect 4]

The wiring body according to any one of aspects 1 to 3, in which, in the expanded portion, a position of an end on another side opposite to the one side changes along the extending direction of the electroconductive line.

### [Aspect 5]

The wiring body according to aspect 3, in which, in the expanded portion, at least a part of the expanded portion is covered with the resin layer when viewed from a direction orthogonal to a main surface of the substrate.

### [Aspect 6]

The wiring body according to any one of aspects 1 to 5, in which an aspect ratio obtained by dividing a height dimension of the electroconductive line by a width dimension of the electroconductive line is greater than 1.

### [Aspect 7]

The wiring body according to any one of aspects 1 to 6, in which a height dimension of the expanded portion is smaller than a height dimension of the tapered portion.

### [Aspect 8]

The wiring body according to any one of aspects 1 to 7, in which an aspect ratio obtained by dividing a height dimension of the expanded portion by a width dimension of the expanded portion is smaller than 1.

### [Aspect 9]

A display device including the wiring body according to any one of aspects 1 to 8.

### REFERENCE SIGNS LIST

1 Light transmissive substrate (substrate)
7 Resin layer
5 Conductor layer
50 Electroconductive line
60 Trench
70 Tapered portion
80 Expanded portion
90 Curved surface
100 Display device
200 Wiring body

What is claimed is:

1. A wiring body comprising: a substrate; and
a conductor layer provided on the substrate and including an electroconductive line extending in a predetermined extending direction, wherein
in a cross-sectional view taken along a direction orthogonal to the extending direction, the electroconductive line includes
a tapered portion in which a width of the electroconductive line increases toward one side away from the substrate in a height direction, and
an expanded portion disposed on the one side with respect to the tapered portion and having the width greater than a width of the tapered portion, and
the expanded portion protrudes outward in a width direction and includes a curved portion.

2. The wiring body according to claim 1, wherein a surface of the electroconductive line on the one side in the height direction is a curved surface protruding toward the one side, and
a protrusion height of the expanded portion is smaller than a protrusion height of the curved surface.

3. The wiring body according to claim 1, further comprising a resin layer provided on the substrate, wherein
the resin layer has a trench in which the electroconductive line is disposed.

4. The wiring body according to claim 1, wherein, in the expanded portion, a position of an end on another side opposite to the one side changes along the extending direction of the electroconductive line.

5. The wiring body according to claim 3, wherein, in the expanded portion, at least a part of the expanded portion is covered with the resin layer when viewed from a direction orthogonal to a main surface of the substrate.

6. The wiring body according to claim 1, wherein an aspect ratio obtained by dividing a height dimension of the electroconductive line by a width dimension of the electroconductive line is greater than 1.

7. The wiring body according to claim 1, wherein a height dimension of the expanded portion is smaller than a height dimension of the tapered portion.

8. The wiring body according to claim 1, wherein an aspect ratio obtained by dividing a height dimension of the expanded portion by a width dimension of the expanded portion is smaller than 1.

9. A display device comprising the wiring body according to claim 1.
